(19) United States
(12) Patent Application Publication
(10) Pub. No.: US 2024/0162684 A1
(43) Pub. Date: May 16, 2024

(54) MULTI-JUNCTION OPTICAL EMITTER WITH MULTIPLE ACTIVE REGIONS ALIGNED TO MULTIPLE WAVELENGTHS

(71) Applicant: Lumentum Operations LLC, San Jose, CA (US)

(72) Inventors: Matthew Glenn PETERS, Menlo Park, CA (US); Jun YANG, Cupertino, CA (US); Guowei ZHAO, Milpitas, CA (US)

(21) Appl. No.: 18/068,248

(22) Filed: Dec. 19, 2022

Related U.S. Application Data
(60) Provisional application No. 63/383,824, filed on Nov. 15, 2022.

(51) Int. Cl. H01S 5/183; H01S 5/30

(52) U.S. Cl. CPC H01S 5/18311; H01S 5/3095

(57) ABSTRACT

In some implementations, an optical emitter includes a set of light emitting junctions; and a set of tunnel junctions separating the set of light emitting junctions, wherein a first light emitting junction, of the set of light emitting junctions, is associated with a peak gain at a first wavelength, and wherein a second light emitting junction, of the set of light emitting junctions, is associated with a peak gain at a second wavelength that is different from the first wavelength.

### CROSS-REFERENCE TO RELATED APPLICATION

This patent application claims priority to U.S. Provisional Patent Application No. 63/383,824, filed on Nov. 15, 2022, and entitled “VERTICAL CAVITY SURFACE EMITTING LASER WITH ACTIVE REGIONS AT MULTIPLE WAVELENGTHS.” The disclosure of the prior application is considered part of and is incorporated by reference into this patent application.

### TECHNICAL FIELD

The present disclosure relates generally to optical emitters and to a multi junction optical emitter with multiple active regions aligned to multiple wavelengths.

### BACKGROUND

An optical emitter, such as a top-emitting vertical cavity surface-emitting laser (VCSEL), a bottom-emitting VCSEL, or an edge emitter, among other examples, may have a set of light emitting junctions. For example, a VCSEL may include a pair of light emitting junctions disposed between a top distributed Bragg reflector (DBR) and a bottom DBR of the VCSEL. Each light emitting junction may be configured for the same wavelength range to enable a greater optical output at the wavelength range than is achieved by a single light emitting junction.

### SUMMARY

In some implementations, an optical emitter includes a set of light emitting junctions; and a set of tunnel junctions separating the set of light emitting junctions, wherein a first light emitting junction, of the set of light emitting junctions, is associated with a peak gain at a first wavelength, and wherein a second light emitting junction, of the set of light emitting junctions, is associated with a peak gain at a second wavelength that is different from the first wavelength.

In some implementations, a vertical cavity surface emitting laser (VCSEL) includes a set of active regions, wherein two or more active regions of the set of active regions are associated with a different peak gain wavelength, wherein adjacent active regions, of the set of active regions, are separated by a quantum well barrier, and wherein the set of active regions have a collective gain above a lasing threshold for a continuous wavelength range.

In some implementations, an optical emitter includes a set of light emitting junctions; and a set of tunnel junctions separating the set of light emitting junctions, wherein a first light emitting junction, of the set of light emitting junctions, is associated with a gain above a first lasing threshold at a first wavelength range, and wherein a second light emitting junction, of the set of light emitting junctions, is associated with a gain above a second lasing threshold at a second wavelength range.

### BRIEF DESCRIPTION OF THE DRAWINGS

FIGS. 1A and 1B are diagrams depicting a top-view of an example optical emitter and a cross-sectional view of example optical emitter along the line X-X, respectively.

FIG. 2 is a diagram of an example implementation associated with a multi junction optical emitter with multiple active regions.

FIG. 3 is a diagram of optical characteristics of optical emitters described herein.

FIGS. 4A-4C are diagrams of an example optical characteristics of a multi junction optical emitter with multiple active regions.

### DETAILED DESCRIPTION

The following detailed description of example implementations refers to the accompanying drawings. The same reference numbers in different drawings may identify the same or similar elements.

An optical emitter, such as a vertical cavity surface emitting laser (VCSEL) may have a plurality of light emitting junctions configured for the same wavelength range to increase an optical output at the wavelength range. For such an optical emitter, a peak power and a threshold current for lasing have an optimum at a specific temperature. Accordingly, performance of such an optical emitter tends to degrade at higher temperatures and lower temperatures. This can occur because an alignment between a VC SEL cavity wavelength (also referred to as the “Fabry-Perot dip” or the “F-P dip”) and a peak gain of a single quantum well occurs at a single temperature.

To achieve a wider wavelength range (e.g., a wider continuous range of wavelengths above a lasing threshold for an operating current without a drop below the lasing threshold) it has been proposed that rather than multiple light emitting junctions configured for the same wavelength range, the multiple light emitting junctions can be configured for different wavelength ranges. In this case, the quantum wells (QWs) of the light emitting junctions have different compositions or thickness to achieve the different wavelength ranges. This could have an effect of flattening a gain curve of an optical emitter over a temperature range. In other words, a range of temperatures at which the optical emitter can function without performance being degraded by more than a threshold amount can be expanded to a wider range of temperatures. However, although the light emitting junctions are configured for different wavelength ranges, the light emitting junctions are part of a single active region resulting in coupling between the QWs associated with the light emitting junctions. Accordingly, instead of multiple QWs able to lase at multiple wavelengths and with multiple quantum states, the multiple QWs have a single quantum state between the multiple quantum states. In this case, the multiple QWs do not end up at an optimum density of states and may not exceed a threshold for lasing. Furthermore, the QWs are typically closely spaced so that the QWs are within a peak of a lasing optical mode standing wave.

Some implementations described herein use a multi junction VCSEL structures with light emitting junctions that are separated by at least a threshold separation to decouple quantum states of the light emitting junctions. In this case, based on spacing out active regions in the multi junction VCSEL structure, an optical emitter can have multiple independent energy states with independent peak gain wavelengths. In this way, the optical emitter can achieve a greater level of performance across a wider wavelength range and/or a wider temperature range than other optical emitters with only a single wavelength range of light-emitting junction or with only quantum-coupled light-emitting junctions.

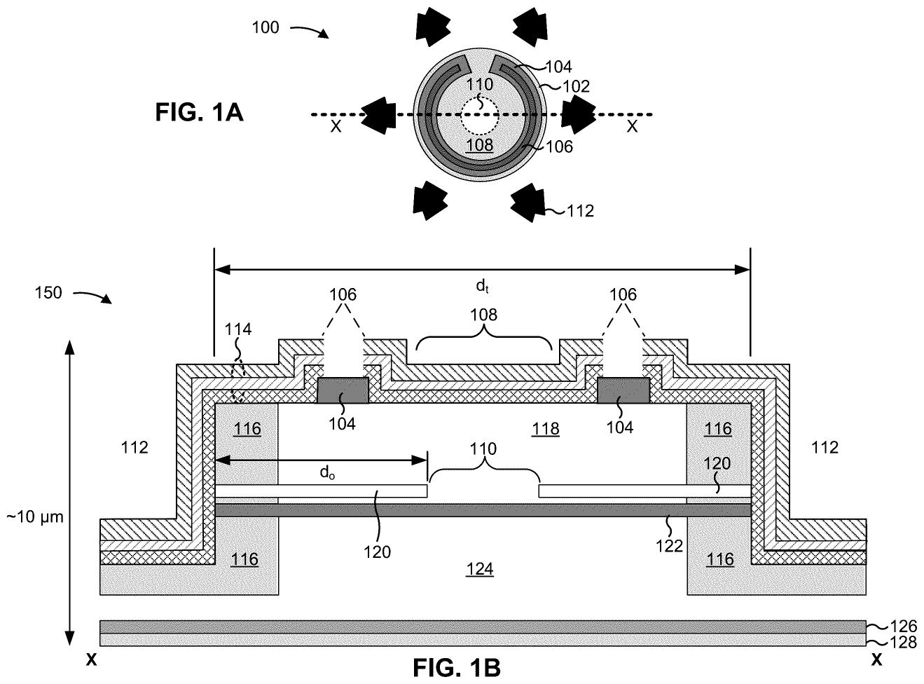

FIGS. 1A and 1B are diagrams depicting a top-view of an example optical emitter 100 and a cross-sectional view 150 of example optical emitter 100 along the line X-X, respectively. As shown in FIG. 1A, optical emitter 100 may include a set of emitter layers constructed in an emitter architecture. In some implementations, optical emitter 100 may correspond to one or more vertical-emitting devices described herein.

As shown in FIG. 1A, optical emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in optical emitter 100.

As shown by the medium gray and dark gray areas in FIG. 1A, optical emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g. a dielectric layer or a passivation layer) of optical emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting optical emitter 100. In the case of a bottom-emitting optical emitter 100, the configuration may be adjusted as needed.

Not shown in FIG. 1A, optical emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium grey area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, optical emitter 100 includes an optical aperture 108 in a portion of optical emitter 100 within the inner radius of the partial ring-shape of ohmic metal layer 104. Optical emitter 100 emits a laser beam via optical aperture 108. As further shown, optical emitter 100 also includes a current confinement aperture 110 (e.g., an oxide aperture formed by an oxidation layer of optical emitter 100 (not shown)). Current confinement aperture 110 is formed below optical aperture 108.

As further shown in FIG. 1A, optical emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, optical emitter 100 may include additional layers, fewer layers, different layers, or differently arranged layers than those shown in FIG. 1A. For example, while optical emitter 100 includes a set of six trenches 112, in practice, other configurations are possible, such as a compact emitter that includes five trenches 112, seven trenches 112, or another quantity of trenches. In some implementations, trench 112 may encircle optical emitter 100 to form a mesa structure dt. As another example, while optical emitter 100 is a circular emitter design, in practice, other designs may be used, such as a rectangular emitter, a hexagonal emitter, an elliptical emitter, or the like. Additionally, or alternatively, a set of layers (e.g., one or more layers) of optical emitter 100 may perform one or more functions described as being performed by another set of layers of optical emitter 100, respectively.

Notably, while the design of optical emitter 100 is described as including a VCSEL, other implementations are possible. For example, the design of optical emitter 100 may apply in the context of another type of optical device, such as a light emitting diode (LED), or another type of vertical emitting (e.g., top emitting or bottom emitting) optical device. Additionally, the design of optical emitter 100 may apply to emitters of any wavelength, power level, and/or emission profile. In other words, optical emitter 100 is not particular to an emitter with a given performance characteristic.

As shown in FIG. 1B, the example cross-sectional view may represent a cross-section of optical emitter 100 that passes through, or between, a pair of trenches 112 (e.g., as shown by the line labeled “X-X” in FIG. 1A). As shown, optical emitter 100 may include a backside cathode layer 128, a substrate layer 126, a bottom mirror 124, an active region 122, an oxidation layer 120, a top mirror 118, an implant isolation material 116, a protective layer 114 (e.g. a dielectric passivation/mirror layer), and an ohmic metal layer 104. As shown, optical emitter 100 may have, for example, a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of optical emitter 100. For example, bottom mirror 124 may include a distributed Bragg reflector (DBR).

Active region 122 may include a layer that confines electrons and defines an emission wavelength of optical emitter 100. For example, active region 122 may be a quantum well.

Oxidation layer 120 may include an oxide layer that provides optical and electrical confinement of optical emitter 100. In some implementations, oxidation layer 120 may be formed as a result of wet oxidation of an epitaxial layer. For example, oxidation layer 120 may be an Al2O3 layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround optical emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of optical emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of optical emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO2 layer, a Si3N4 layer, an Al2O3 layer, or other layers) deposited (e.g., by chemical vapor deposition, atomic layer deposition, or other techniques) on one or more other layers of optical emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, optical emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, optical emitter 100 may include additional layers, fewer layers, different layers, differently constructed layers, or differently arranged layers than those shown in FIG. 1B. Additionally, or alternatively, a set of layers (e.g., one or more layers) of optical emitter 100 may perform one or more functions described as being performed by another set of layers of optical emitter 100 and any layer may comprise more than one layer.

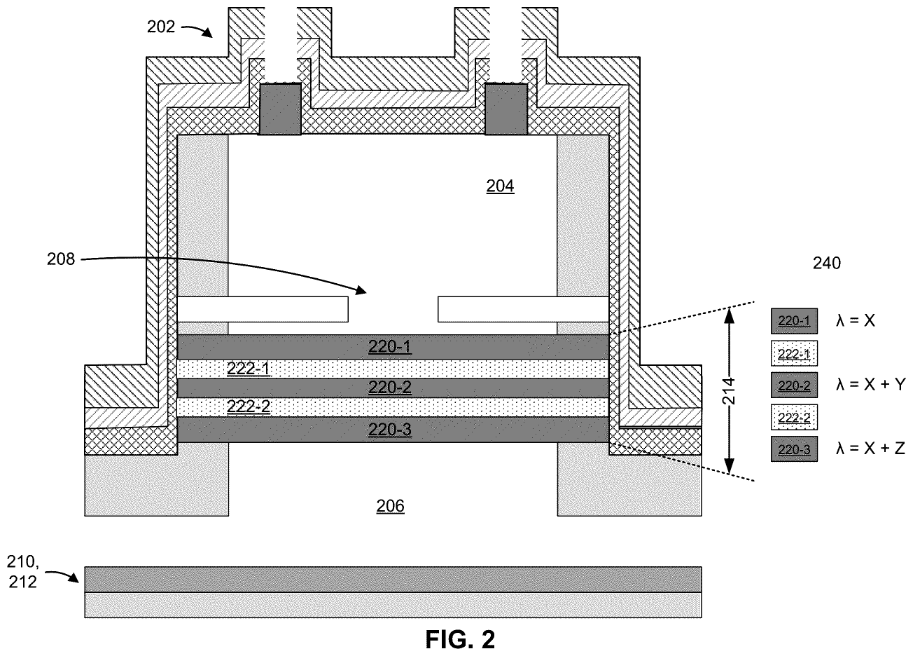

FIG. 2 is a diagram of an example optical emitter 200 associated with a multi junction VCSEL with multiple active regions having different peak gain wavelengths. As shown in FIG. 2, example optical emitter 200 includes an anode 202, a top DBR 204, a bottom DBR 206, a confinement section 208, a substrate 210, a cathode 212, and an active region 214 that is disposed between the top DBR 204 and the bottom DBR 206. In some implementations, optical emitter 200 may include additional components, fewer components, or different components. In some implementations, optical emitter 200 may correspond to optical emitter 100.

As further shown in FIG. 2, the active region 214 may include a set of light emitting junctions 220 and a set of tunnel junctions 222. For example, the active region 214 may include a first light emitting junction 220-1, a second light emitting junction 220-2, and a third light emitting junction 220-3. Additionally, or alternatively, the active region 214 may include a first tunnel junction 222-1 and a second tunnel junction 222-2. In this case, as shown, the tunnel junctions 222 are sandwiched between light emitting junctions 220 to decouple quantum states of the light emitting junctions 220. For example, the tunnel junctions 222 may have a set of semiconductor layers with a total thickness above a threshold, such that a tunnel junction 222 decouples quantum well energy states of adjacent light emitting junctions 220.

In some implementations, the set of tunnel junctions 222 may provide separation between active regions associated with light emitting junction 220 (e.g., a set of active regions that, collectively, form active region 214). In some implementations, the tunnel junctions 222 may have at least a threshold thickness to decouple pairs of light emitting junctions 220. For example, the tunnel junctions 222 may provide a spacing of at least 500 nanometers (nm), at least 200 nm, at least 100 nm, or at least 50 nm, among other examples. In some implementations, the set of light emitting junctions 220 may be positioned to have overlapping quantum well gains. For example, active regions of active region 214 (e.g., corresponding to each light emitting junction 220) may be positioned within a threshold amount of an optical mode standing wave for overlap with a quantum well gain associated with other active regions.

As further shown in FIG. 2, and by diagram 240, the light emitting junctions 220 may be configured with different peak gain wavelengths. For example, the first light emitting junction 220-1 may have a first wavelength X, the second light emitting junction 220-2 may have a second wavelength (offset from the first wavelength) of X+Y, and the third light emitting junction 220-3 may have a third wavelength (offset from the first wavelength) of X+Z. The different wavelengths of the light emitting junctions 220 may be based on differing compositions or thicknesses of quantum wells associated with the light emitting junctions 220 or quantum well barriers associated with the tunnel junctions 222. In some implementations, the active regions of active region 214 may have multiple quantum wells. For example, a first active region may include between 1 and 5 quantum wells with the same material composition and thickness as each other and a second active region may include another between 1 and 5 quantum wells with the same material composition and thickness as each other but different than those of the first active region.

In some implementations, the optical emitter 200 may have two or more light emitting junctions 220 with the same peak gain wavelength. For example, first light emitting juncition 220-1 may be formed from a plurality of light emitting junctions 220 having a peak gain wavelength at wavelength X−Y and second light emitting junction 220-2 may be formed from a plurality of light emitting junctions 220 having a peak gain wavelength at wavelength X+Y. Additionally, or alternatively, first light emitting junction 220-1 may be formed from a plurality of light emitting junctions 220 having a peak gain wavelength at wavelength X, second light emitting junction 220-2 may be formed from a plurality of light emitting junctions 220 having a peak gain wavelength at wavelength X+Y, and/or third light emitting junction 220-3 may be formed from a plurality of light emitting junctions 220 having a peak gain wavelength at a wavelength of X+Z. In other words, the optical emitter 200 may have two or more light emitting junctions 220 with different peak gain wavelengths and two or more light emitting junctions 220 with the same peak gain wavelength. In this case, by having a plurality of light emitting junctions 220 with the same peak gain wavelength, the optical emitter 200 may achieve a greater peak gain at the peak gain wavelength than is achieved by a single light emitting junction 220.

In some implementations, the optical emitter 200 may have another different quantity of light emitting junctions. For example, the optical emitter 200 may be a 2-junction VCSEL with active regions at +/−Y/2 nm around a center peak gain wavelength of X nm (e.g., active regions at X+Y/2 and X−Y/2). Additionally, or alternatively, the optical emitter 200 may have other quantities of light emitting junctions, such as three or more light emitting junctions, with different peak gain wavelengths, such as three or more different peak gain wavelengths. For example, the optical emitter 200 may be a 3-junction VCSEL with active regions at +/−Y nm around a center peak gain wavelength of X nm (e.g., active regions at X−Y, X, and X+Y); a 5-junction VCSEL with active regions at +/−Y and Y/2 nm around a center peak gain wavelength of X nm (e.g., active regions at X−Y, X−Y/2, X, X+Y/2, and X+Y); or a higher quantity of junctions; among other examples. In another configuration, as described above, a multi junction VCSEL may have multiple active regions with the same peak wavelength resulting in, for example, a 6-junction VCSEL with 2 active regions at +/−Y nm around a center peak gain wavelength of X nm (e.g., 2 active regions at X−Y, 2 active regions at X, and 2 active regions at X+Y). In other configurations, the wavelength spacings may not be evenly spaced (e.g. the wavelength spacings may not be even fractions of spacing Y).

Other combinations or quantities of junctions are contemplated. Accordingly, in some implementations, the value for X may be based on an application of the optical emitter 200. For example, X may be in a range of 600 nm to 1500 nm, with a value at, for example, 850 nm, 905 nm, 940 nm, 980 nm, 1150 nm, 1380 nm or 1550 nm, among other examples. In one case, for a value of X of 940 nm, the optical emitter 200 may be configured to operate at peak efficiency at 50 degrees C. (° C.). In this case, the optical emitter 200 may operate at peak efficiency when the F-P dip is 940 nm at 50° C. In some implementations, a separation between active region peak gain wavelengths (e.g., a value of Y) may be based on an operating temperature range for the optical emitter 200. For example, Y may have a value in a range of 5 nm to 20 nm to achieve an operating temperature range in a range of 0° C. to 100° C. Greater values for Y are contemplated to achieve even wider temperature ranges beyond 0° C. to 100° C. For example, for automotive applications, the optical emitter may have a temperature range of at least −40° C. to 125° C. ambient temperature without performance being degraded below a threshold or a failure of operation. In some implementations, a quantity of different active region wavelengths may be controlled using an epitaxial growth control technique. For example, the optical emitter 200 may be configured for 2 or 3 different wavelength targets with relatively small quantities of junctions (e.g., 6 or fewer junctions). At higher quantities of junctions (e.g., 6 or more junctions), the optical emitter 200 may be configured for 4 or 5 different wavelength targets to achieve stable operation across a wide wavelength range as described herein.

In some implementations, optical emitter 200 may have a particular order of active regions associated with light emitting junctions 220. For example, the optical emitter 200 may have active regions with a highest carrier density or a lowest peak gain wavelength closest to a current confining structure, such as confinement section 208 or an oxidation aperture, which may improve an efficiency of the optical emitter 200 (e.g., such as when the optical emitter 200 operates at higher temperatures) relative to a different order of active regions. Additionally, or alternatively, the optical emitter 200 may have lower strain active regions (e.g., 920 nm relative to 940 nm) which may be closest to a current confining structure with a higher carrier density. In some implementations, to extend the operation to higher temperatures the optical emitter 200 may have an active region with a lowest wavelength or a largest GCO and/or a highest temperature active region closer to an oxidation aperture or closer to a middle of a cavity of the optical emitter 200.

As indicated above, FIG. 2 is provided as an example. Other examples may differ from what is described with regard to FIG. 2.

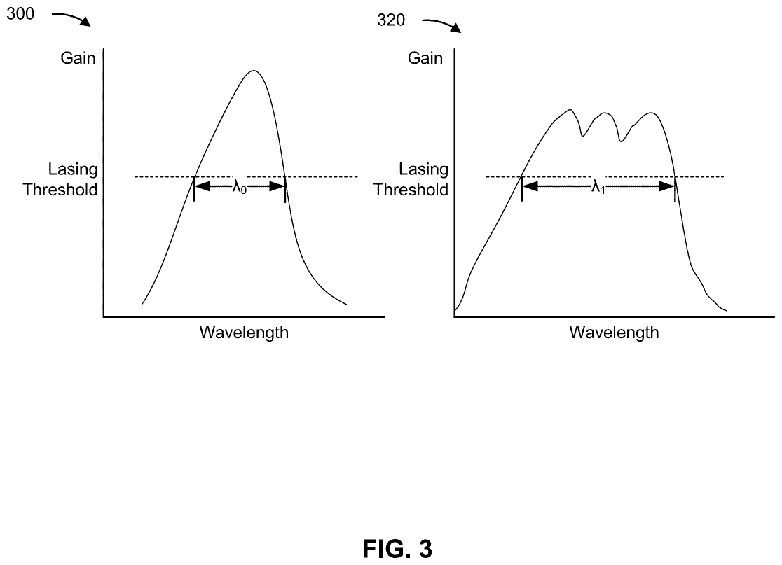

FIG. 3 is a diagram of optical characteristics of optical emitters described herein. As shown in FIG. 3, diagram 300 illustrates an example of a wavelength versus gain for the optical emitter 100 (e.g., an optical emitter with multiple junctions all with the same peak gain wavelength) and diagram 320 illustrates an example of a wavelength versus gain for the optical emitter 200 (e.g., an optical emitter with multiple junctions having different peak gain wavelengths). The optical emitter 100 exhibits a single gain peak and a continuous wavelength range λ₀ above a lasing threshold for efficient lasing. In contrast, the optical emitter 200 includes multiple gain peaks, corresponding to the multiple light emitting junctions 220 of the optical emitter 200, and a continuous wavelength range λ₁ above a lasing threshold. As shown, by using multiple light emitting junctions 220, the optical emitter 200 achieves a flattened gain peak and, accordingly, a wider continuous wavelength range (e.g., a wider wavelength region bounded by a lower wavelength bound and an upper wavelength bound) than is achieved by optical emitter 100 (in other words, λ₁>λ₀). In this way, the optical emitter 200 achieves efficient lasing over a wider wavelength range than the optical emitter 100.

As indicated above, FIG. 3 is provided as an example. Other examples may differ from what is described with regard to FIG. 3.

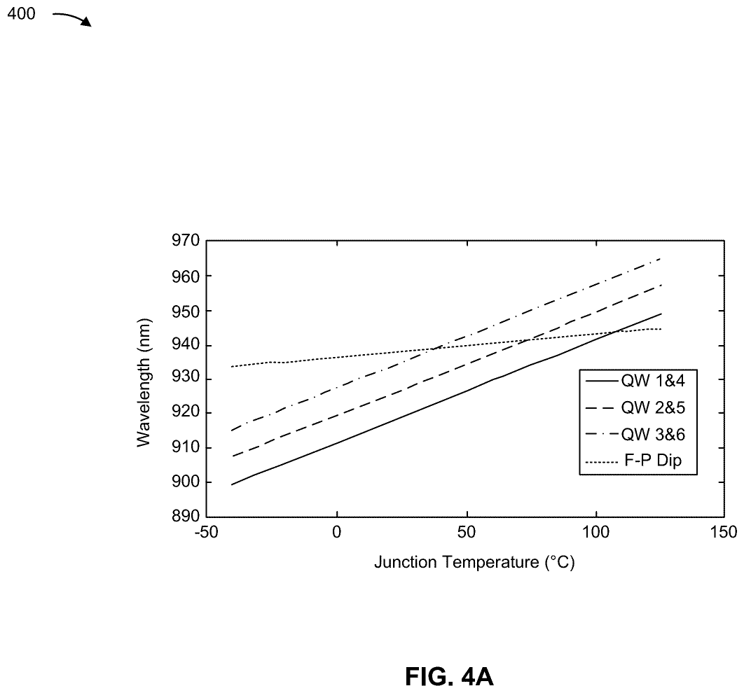

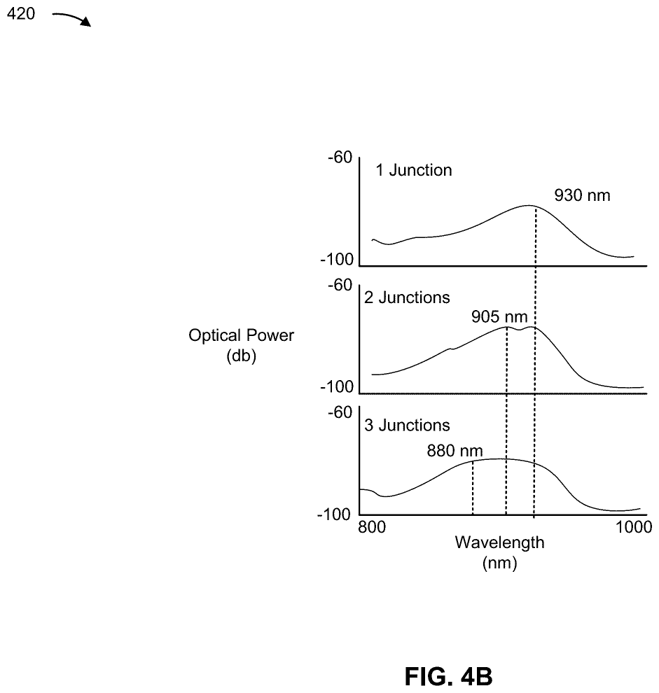

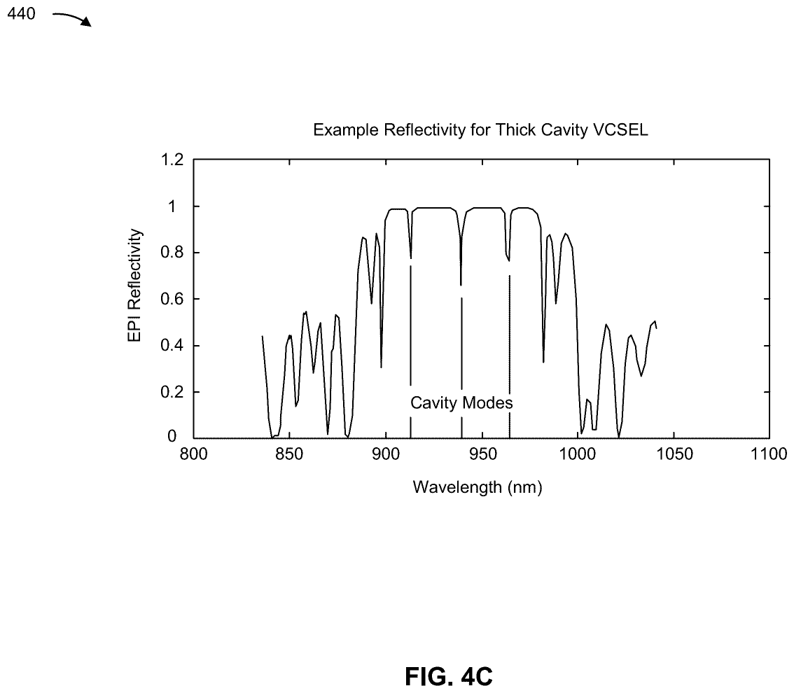

FIGS. 4A-4C are diagrams of an example optical characteristics of a multi junction optical emitter with multiple active regions.

As shown in FIG. 4A, diagram 400 shows an example 6-junction VCSEL. For example, diagram 400 illustrates an F-P dip versus temperature and peak gain wavelengths of different active regions. In this case, the F-P dip versus temperature is for a target of 940 nm at 50° C. and a shift of approximately 0.07 nm/° C. The peak gain wavelengths of the other active regions (e.g., a first active region from a QW 1 and a QW 4; a second active region from a QW 2 and a QW 5; and a third active region from a QW 3 and a QW 6) have a shift of approximately 0.30 nm/° C. Here, the active regions have a spacing of approximately 8 nm. To achieve operation from 0° C. to 100° C., the 6-junction VCSEL is configured to have the three active regions cross the F-P Dip from 40° C. (the first active region) to 105° C. (the third active region). In some implementations, the 6-junction VCSEL may have indium-gallium-arsenide (InGaAs) QWs, which have sufficient gain at the lower temperatures (e.g., below 40° C.) at an operating current (e.g., a peak gain value is higher at lower temperatures) that the gain peaks and the F-P dip do not need to be aligned at the lower temperatures. In contrast, at higher temperatures (e.g., approximately 100° C.), the peak gain value drops at the operating current. Accordingly, by having the gain peak aligned with the F-P dip at the higher temperatures, the 6-junction VC SEL achieves efficient lasing without an increase in operating current.

As shown in FIG. 4B, diagram 420 shows an example of growth (e.g., using epitaxial growth control) of a multi junction VCSEL with different target wavelengths. In this case, active regions are separated by 25 nm (e.g., 880 nm, 905 nm, and 930 nm). Diagram 420 shows an example of wavelength versus optical power, measured using electro-luminescence (EL), as the multi junction VCSEL is grown from a single junction VCSEL to a multi junction VCSEL. In this case, as shown, adding the additional junctions spreads out the gain peak shape from a single, relatively sharp peak, to three relatively flat peaks (which may, collectively, form a single peak).

As shown in FIG. 4C, and by diagram 440, rather than a single, continuous lasing region, a multi junction VCSEL described herein can have different wavelength active regions resulting in lasing at different discrete wavelengths. Diagram 440 shows a reflectivity of a multi-junction VCSEL with multiple cavity modes for lasing at multiple different discrete wavelengths. In this case, such a multi junction VCSEL may lase at different cavity mode wavelengths by using active regions targeting peak gain at different wavelengths (e.g., that match the different cavity mode wavelengths). In some implementations, the different cavity mode wavelengths are discrete, discontinuous wavelength ranges (e.g., there is an intermediate wavelength range between two cavity mode wavelengths at which the multi junction VCSEL does not lase). In this case, the multi junction VCSEL may be aligned to an optical element that directs light in different directions based on wavelengths. For example, the multi junction VCSEL may be disposed in an optical system that includes a wavelength sensitive optic (e.g., a grating) configured to direct different wavelengths of light from the multi junction VCSEL in different directions (e.g., a first wavelength range of light is directed in a first direction and a second wavelength range of light is directed in a second, different direction).

As indicated above, FIGS. 4A-4C are provided as examples. Other examples may differ from what is described with regard to FIGS. 4A-4C.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical emitter, comprising:
a set of light emitting junctions; and
a set of tunnel junctions separating the set of light emitting junctions,
wherein a first light emitting junction, of the set of light emitting junctions, is associated with a peak gain at a first wavelength, and
wherein a second light emitting junction, of the set of light emitting junctions, is associated with a peak gain at a second wavelength that is different from the first wavelength.

2. The optical emitter of claim 1, wherein the optical emitter is a multi junction vertical cavity surface emitting laser (VCSEL).

3. The optical emitter of claim 1, wherein each tunnel junction, of the set of tunnel junctions, is sandwiched by a pair of light emitting junctions of the set of light emitting junctions.

4. The optical emitter of claim 1, wherein a thickness of a set of semiconductor layers between adjacent light emitting junctions of the set of light emitting junctions decouples quantum well energy states of the adjacent light emitting junctions.

5. The optical emitter of claim 4, wherein the set of semiconductor layers includes a tunnel junction of the set of tunnel junctions.

6. The optical emitter of claim 1, wherein the first wavelength and the second wavelength are offset, such that a gain from the optical emitter is above a lasing threshold from a lower wavelength to an upper wavelength.

7. The optical emitter of claim 6, wherein a size of a wavelength region bounded by the lower wavelength and the upper wavelength is greater than a size of a wavelength region associated with only the first light emitting junction or only the second light emitting junction.

8. The optical emitter of claim 1, wherein the set of light emitting junctions includes three or more light emitting junctions with peak gains at three or more wavelengths.

9. A vertical cavity surface emitting laser (VCSEL), comprising:
a set of active regions,
wherein two or more active regions of the set of active regions are associated with a different peak gain wavelength,
wherein adjacent active regions, of the set of active regions, are separated by a tunnel junction, and
wherein the set of active regions each have a gain above a lasing threshold for a wavelength range.

10. The VC SEL of claim 9, wherein the wavelength range is a range from 5 nanometers to 20 nanometers.

11. The VCSEL of claim 9, wherein the tunnel junction is associated with a spacing of at least 50 nanometers.

12. The VCSEL of claim 9, wherein an active region, of the set of active regions, is associated with a quantum well, and
wherein a peak gain wavelength of the active region is based on at least one of a composition or a thickness of the quantum well.

13. The VCSEL of claim 9, wherein an order of active regions in the VCSEL is based on a carrier density, such that an active region, of the set of active regions, with a highest carrier density is closest to a current confining structure of the VCSEL.

14. The VCSEL of claim 9, wherein an order of active regions in the VCSEL is based on a peak gain wavelength, such that an active region, of the set of active regions, with a lowest peak gain wavelength is closest to a current confining structure of the VCSEL or to a middle of a cavity of the VCSEL.

15. The VCSEL of claim 9, further comprising:
a plurality of active regions having a same peak gain wavelength.

16. An optical emitter, comprising:
a set of light emitting junctions; and
a set of tunnel junctions separating the set of light emitting junctions,
wherein a first light emitting junction, of the set of light emitting junctions, is associated with a gain above a first lasing threshold at a first wavelength range, and
wherein a second light emitting junction, of the set of light emitting junctions, is associated with a gain above a second lasing threshold at a second wavelength range.

17. The optical emitter of claim 16, wherein the first wavelength range at least partially overlaps with the second wavelength range.

18. The optical emitter of claim 16, wherein the first wavelength range is discontinuous with the second wavelength range, such that the optical emitter does not lase at an intermediate wavelength range between the first wavelength range and the second wavelength range.

19. The optical emitter of claim 16, further comprising:
a wavelength sensitive optic configured to direct light in the first wavelength range in a first direction and light in the second wavelength range in a second direction that is different from the first direction.

20. The optical emitter of claim 19, wherein the wavelength sensitive optic is a grating.
